(19) United States
(12) Patent Application Publication
(10) Pub. No.: US 2025/0036833 A1
(43) Pub. Date: Jan. 30, 2025

(54) INFORMATION PROCESSING APPARATUS, COMPUTER-READABLE RECORDING MEDIUM, AND INFORMATION PROCESSING METHOD

(71) Applicants: SoftBank Corp., Tokyo (JP); NeuralX Inc., Los Angeles, CA (US)

(72) Inventors: Yuko ISHIWAKA, Tokyo (JP); Masaki NAKADA, Los Angeles, CA (US)

(21) Appl. No.: 18/347,551

(22) Filed: Jul. 5, 2023

(51) Int. Cl. G06F 30/23

(52) U.S. Cl. CPC G06F 30/23

(57) ABSTRACT

There is provided an information processing apparatus including: a model generation unit that generates, by simulating contraction of a plurality of muscle fibers which make up a muscle, a muscle model that simulates a movement of the muscle; and a simulation unit that simulates, by using the muscle model to simulate movements of a plurality of muscles which are included in a human face, a movement of the human face.

### BACKGROUND

### 1. Technical Field

The present invention relates to an information processing apparatus, a computer-readable storage medium, and an information processing method.

### 2. Related Art

In a field of CG (Computer Graphics), a simulation technique based on a muscle contraction has been known (see, for example, Non-Patent Document 1 to Non-Patent Document 6). In a simulation technique in the related art, a so-called Hill-type model, a so-called CPG (Central Pattern Generator), or the like has been used.

### LIST OF CITED REFERENCES

### Non-Patent Document

Non-Patent Document 1: Thomas Geitenbeek, Michiel van de Panne, A. F. v. d. s. Flexible muscle-based locomotion for bipedal creatures. ACM Transactions on Graphics, (206), 2013.
Non-Patent Document 2: Jack M. Wang, Samuel R. Hmner, S. L. V. K. Optimizing locomotion controllers using biologically-based actuators and objectives. ACM Trans. Graph, 31(4), 2012.
Non-Patent Document 3: Yoonsang Lee, Moon Seok Park, T. K. J. L. Locomotion control for many-muscle humanoids. ACM Transactions on Graphics, 33(6), 2014.
Non-Patent Document 4: Sehee Min, Jungdam Won, S. L. J. P. J. L. Softcon: simulation and control of soft-bodied animals with biomimetic actuators. ACM Transactions on Graphics, 38(6):208:1-208:12, 2019.
Non-Patent Document 5: Cecila Laschi, Matteo Cianchetti, B. M. L. m. M. F. P. D. Soft robot arm inspired by the octopus. Advanced Robotics, 26(7):709-727, 2012.
Non-Patent Document 6: Jungdam Won, Jongho Park, K. K. J. L. How to train your dragon: Example-guided control of flapping flight. ACM Transactions on Graphics, 36(4):1:1-1:12, 2017.

### BRIEF DESCRIPTION OF THE DRAWINGS

FIG. 1 schematically shows an example of information processing apparatus 100.

FIG. 2 schematically shows an example of a structure of an information processing apparatus 100.

FIG. 3 schematically shows an example of a flow of a process by the information processing apparatus 100.

FIG. 4 schematically shows an example of muscle fiber structure.

FIG. 5 schematically shows an example of isocurves extraction for fibers orientation.

FIG. 6 schematically shows an example of HILL's functional model of the muscle.

FIG. 7 shows linearized stress-strain relation for the parallel element.

FIG. 8 shows linearized stress-strain relation for the series element.

FIG. 9 shows force-velocity relation of fully activated muscle tissue when CE is at optimal length.

FIG. 10 shows force-length relation of muscle tissue due to an active force.

FIG. 11 shows example of an activation function α(t) for a given neural excitation u(t) versus time (s).

FIG. 12 schematically shows an example of a hardware configuration of computer 1200 functioning as the information processing apparatus 100.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiment are essential to the solution of the invention.

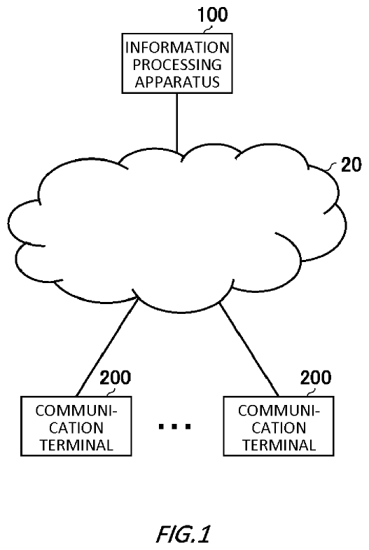

FIG. 1 schematically shows an example of an information processing apparatus 100. The information processing apparatus 100 has a function of executing a simulation of a skeletal muscle. The skeletal muscle may be simply described as a muscle.

In the related art, in a simulation technique based on a muscle contraction, for example, a method has been adopted for registering a most contracted state and a most stretched state for each muscle and performing complementing between the two states. However, in such a related art, it is difficult to accurately simulate a movement of the muscle, and the movement may be different from an actual movement to cause a weird feeling.

In contrast with this, the information processing apparatus 100 according to the present embodiment generates a muscle model that simulates the movement of the muscle by simulating contraction of a plurality of muscle fibers which make up the muscle. Then, for example, by using the generated muscle model to simulate movements of a plurality of muscles included in a human face, the information processing apparatus 100 simulates a movement of the human face. This makes it possible to more accurately realize the movement of the human facial muscle, and it is possible to realize the movement of the human face that does not cause a weird feeling or is less likely to cause the weird feeling.

The information processing apparatus 100 may be applied to various fields. Then, for example, by using the muscle model to simulate the movements of the plurality of muscles which are included in the human face, the information processing apparatus 100 generates an elaborate CG animation of the human face. The information processing apparatus 100 may cause the generated CG animation to be displayed on a display included in the information processing apparatus 100. The information processing apparatus 100 also transmits, for example, the generated CG animation to a communication terminal 200 via a network 20.

The communication terminal 200 may be any communicable terminal such as a PC (Personal Computer), a tablet terminal, a smartphone, a robot, or a home appliance. The information processing apparatus 100 and the communication terminal 200 may communicate with each other via the network 20. The network 20 may include the Internet. The network 20 may include a LAN (Local Area Network). The network 20 may include a mobile communication network. The mobile communication network may conform to any of the LTE (Long Term Evolution) communication system, the 5G (5th Generation) communication system, the 3G (3rd Generation) communication system, and the 6G (6th Generation) communication system and the communication system of the subsequent generation.

For example, by using the muscle model to simulate the movement of the human face, the information processing apparatus 100 may generate synthetic data for face authentication. The information processing apparatus 100 may execute machine learning in which the generated synthetic data is used. The information processing apparatus 100 may transmit the generated synthetic data to the communication terminal 200.

For example, the information processing apparatus 100 uses the muscle model to simulate the human face, and generates three-dimensional data of the human face which includes information on the movement of the muscle.

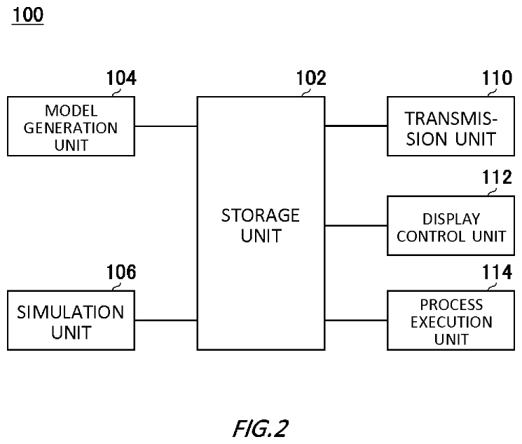

FIG. 2 schematically shows an example of a functional configuration of the information processing apparatus 100. The information processing apparatus 100 includes a storage unit 102, a model generation unit 104, a simulation unit 106, a transmission unit 110, a display control unit 112, and a process execution unit 114. It should be noted that it is not necessarily essential that the information processing apparatus 100 includes all of these.

The storage unit 102 stores various types of information. The storage unit 102 may store information used for generating the muscle model.

The model generation unit 104 generates the muscle model that simulates the movement of the human facial muscle. The model generation unit 104 generates, by simulating the contraction of the plurality of muscle fibers which make up the human facial muscle, the muscle model that simulates the movement of the muscle. For each of the plurality of muscles included in human muscles of facial expression, by simulating the contraction of the plurality of muscle fibers which make up the muscle, the model generation unit 104 may generate the muscle model that simulates the movements of the plurality of muscles. The model generation unit 104 causes the generated muscle model to be stored in the storage unit 102.

Each of a plurality of parts which make up the human face has one or more muscles. For example, the human face includes muscles of the mouth, muscles of the nose, muscles of the cranium and neck, muscles of the external ear, and muscles of the eyelid. The muscles of the mouth include the Orbicularis Oris muscle, the Risorius muscle, the Buccinator muscle, the Levator labii superioris, the Depressor labii inferioris, the Levator labii superioris alaeque nasi, the Mentalis, the Levator anguli oris, the Depressor anguli oris, the Zygomaticus major, and the Zygomaticus minor. The muscles of the nose include the Nasalis muscle and the Procerus muscle. The muscles of the cranium and neck include the Occipitofrontalis muscle and the Platysma muscle. The muscles of the external ear include Auricular muscles. The muscles of the eyelid include the Orbicularis oculi muscle and the Corrugator supercilia muscle.

The model generation unit 104 may simulate, for each of the plurality of muscles which make up a part of the human face, the contraction of the plurality of muscle fibers which make up the muscle. For example, the model generation unit 104 generates, by simulating the contraction of the plurality of muscle fibers which make up the orbicularis oris muscle, the muscle model that can simulate the movement of the orbicularis oris muscle.

The model generation unit 104 may more finely divide each of the plurality of muscles which make up a part of the human face to simulate, for each of the divided muscles, the contraction of the plurality of muscle fibers which make up the muscle. For example, the model generation unit 104 divides the orbicularis oris muscle into a plurality of parts, and simulates the contraction of the plurality of muscle fibers which make up the muscle for each divided muscle.

The model generation unit 104 may use a finite element method to generate the muscle model. By using the finite element method, it is possible to appropriately simulate the movement of the muscle which contracts as a whole as a result of the contraction of the plurality of muscle fibers.

The storage unit 102 may store muscle shape data which indicates a shape of the human facial muscle and which is used to execute a simulation in which the finite element method is used. The muscle shape data is generated, for example, by using MRI (Magnetic Resonance Imaging). The muscle shape data may be generated, for example, by using CT (Computed Tomography). The muscle shape data may be an existing model such as a Zygote model in humans.

When the muscle shape data is in a format that can be processed by the model generation unit 104, the model generation unit 104 may use the muscle shape data as it is to generate the muscle model. When the muscle shape data is not in a format that can be processed by the model generation unit 104, the model generation unit 104 may convert the muscle shape data into the format that can be processed and then generate the muscle model.

The model generation unit 104 may generate the muscle model that simulates the contraction of the plurality of muscle fibers, for example, by using the finite element method to calculate an approximate solution of an equation representing the contraction of the plurality of muscle fibers which make up the human facial muscle. As a specific example, the model generation unit 104 generates the muscle model based on a so-called Hill-type model that is constituted by three elements as a CE (Contractile), a SE (Series), and a PE (Parallel).

The model generation unit 104 may divide, into a plurality of groups, the plurality of muscle fibers which make up the human facial muscle, and generate, for one or some of the plurality of groups, the muscle model that simulates contraction of each of a plurality of muscle fibers which are included in the one or some of the plurality of groups. The model generation unit 104 may generate, for the one or some of the groups described above, the muscle model that simulates the contraction of each of all of the muscle fibers included in the group. The model generation unit 104 may generate, for some other group or groups among the plurality of groups, the muscle model that simulates contraction of only one or some of a plurality of muscle fibers which are included in the one or some of the plurality of groups. The model generation unit 104 may generate, for some other group or groups among the plurality of groups, the muscle model that integrally simulates contraction of a plurality of muscle fibers which are included in the one or some of the plurality of groups. In this way, by having a function of dividing, into the plurality of groups, the plurality of muscle fibers which make up the human facial muscle; simulating the contraction of each of the plurality of muscle fibers which are included in the group by the grouping; simulating the contraction of only some of the plurality of muscle fibers; or integrally simulating the contraction of the plurality of muscle fibers, it is possible to set the simulation in accordance with a load, to be executable. For example, in a case where the simulation is attempted to contract each of all of the muscle fibers, when it takes months or even years for a calculation time, it is possible to reduce the calculation time while a precision is maintained as much as possible, by thinning out or integrally calculating the less important muscle fibers among the plurality of muscle fibers.

For example, the model generation unit 104 divides, into a plurality of groups, the plurality of muscle fibers which make up the human facial muscle in descending order of influence on the movement of the muscle. For a group which has a greatest influence on the movement of the muscle among the plurality of groups, the model generation unit 104 may generate the muscle model that simulates contraction of each of a plurality of muscle fibers which are included in the group. As the influence on the movement of the muscle decreases in the plurality of groups, the model generation unit 104 may decrease a ratio of simulating the contraction in the plurality of the muscle fibers. This makes it possible to appropriately reduce a processing load, by accurately simulating the muscle fibers which have great influences on the movement of the muscle and thinning out processing of the muscle fibers which have small influences.

The model generation unit 104 may generate the muscle model that simulates contraction of each of a plurality of muscle fibers which are located at an external boundary of the muscle and simulate contraction of only one or some of a plurality of muscle fibers which are located at locations other than the boundary, among the plurality of muscle fibers which make up the human facial muscle. For example, the model generation unit 104 generates the muscle model that simulates the contraction of all of the plurality of muscle fibers which are located at the external boundary of the muscle. In many cases, the muscle fiber located at the external boundary of the muscle has a greater influence on the movement of the muscle in comparison with the muscle fiber which is located at the location other than the boundary. In this manner, it is possible to appropriately reduce a processing load, by accurately simulating the muscle fibers which have great influences on the movement of the muscle and thinning out processing of the muscle fibers which have small influences.

The model generation unit 104 may generate the muscle model that simulates contraction of each of ta plurality of muscle fibers which have higher degrees of freedom and simulate contraction of only one or some of a plurality of muscle fibers which have lower degrees of freedom, among the plurality of muscle fibers which make up the human facial muscle. The muscle fiber which has a high degree of freedom is considered to have a greater influence on the movement of the muscle in comparison with the muscle fiber which has a low degree of freedom. In this manner, it is possible to appropriately reduce a processing load, by accurately simulating the muscle fibers which have great influences on the movement of the muscle and thinning out processing of the muscle fibers which have small influences.

The simulation unit 106 simulates, by using the muscle model stored in the storage unit 102 to simulate the movements of the plurality of muscles which are included in the human face, the movement of the muscle of the human face.

For example, by using the muscle model that simulates movements of the muscles of the entire human face to simulate the movement of the muscles of the entire human face, the simulation unit 106 simulates the movement of the entire human face.

The simulation unit 106 may simulate the movement of the human face to generate various types of data. The simulation unit 106 causes the generated data to be stored in the storage unit 102.

For example, by using the muscle model to simulate the movements of the plurality of muscles which are included in the human face, the simulation unit 106 generates the CG animation of the human face. For example, by using the muscle model to simulate the movement of the human face, the simulation unit 106 generates the synthetic data for face authentication.

For example, the simulation unit 106 uses the muscle model to simulate the movement of some or all of the human muscles of facial expression, and generates the three-dimensional data of a part or the whole of the human face which includes information on the movement of the muscle.

The transmission unit 110 transmits, to an outside, the data which is stored in the storage unit 102. For example, the transmission unit 110 transmits the muscle model generated by the model generation unit 104 to the communication terminal 200 or the like. For example, the transmission unit 110 transmits the CG animation generated by the simulation unit 106 to the communication terminal 200 or the like. For example, the transmission unit 110 transmits, to the communication terminal 200 or the like, the three-dimensional data of the human face which is generated by the simulation unit 106 and includes the information on the movement of the muscle.

The display control unit 112 causes the data stored in the storage unit 102 to be displayed on the display included in the information processing apparatus 100. For example, the display control unit 112 causes the CG animation generated by the simulation unit 106 to be displayed on the display included in the information processing apparatus 100.

The process execution unit 114 executes a process by using the data stored in the storage unit 102. For example, the process execution unit 114 executes the machine learning in which the synthetic data generated by the simulation unit 106 is used.

FIG. 3 schematically shows an example of a flow of a process by the information processing apparatus 100. Here, a flow of a process in a case where the information processing apparatus 100 generates the muscle model of the human face and generates the CG animation in which the human face changes in various ways, will be described.

In step (the step may be abbreviated as S) 102, the model generation unit 104 acquires, from the storage unit 102, the data used for generating the muscle model. The model generation unit 104 may acquire the muscle shape data which indicates the shape of the human facial muscle that serves as a target.

In S104, by using the data acquired in S102 to simulate the contraction of the plurality of muscle fibers which make up the human facial muscle, the model generation unit 104 generates the muscle model that simulates the movement of the human facial muscle.

In S106, by using the muscle model generated by the model generation unit 104 in S104 to simulate the movements of the plurality of muscles which are included in the human face, the simulation unit 106 simulates the movement of the human face to generate the CG animation in which the human face changes in various ways. In S108, the display control unit 112 performs a display output of the CG animation generated by the simulation unit 106 in S106.

A specific example of the process by the information processing apparatus 100 will be described below.

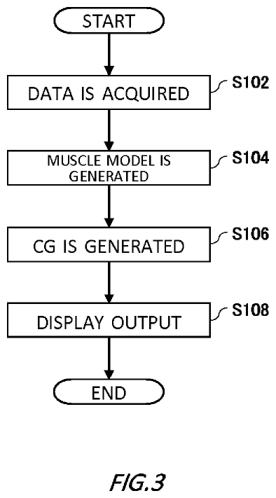

FIG. 4 schematically shows an example of muscle fiber structure.

Skeletal muscles are voluntary muscles, as they contract and relax consciously (Not like smooth muscles as cardiac muscles which contract involuntary). Some of the main functions of skeletal muscle tissue is to induce motion, provide stability and move substances within the body. Skeletal muscles exhibit a hierarchical structure when observed at different levels of magnification as illustrated in the FIG. 4. A muscle fiber 300 includes myofibrils 302, muscle filaments 304, sarcolemma 306, and sarcoplasm 308.

A muscle, at the largest scale, is made up of many bundles of muscle fascicles. These are composed of long cylindrical cells, namely, muscle fibers. Muscle fibers consist of many force-producing cells, known as sarcomeres. Sarcomeres are the basic contractile (CE) part of the muscle tissue. Myofibrils consist of numerous amounts of sarcomeres arranged in series and parallel to each other. A group of myofibrils arranged in parallel make up a muscle fiber. This repetitive nature of the structure of the muscle tissue suggests that, in terms of its mechanical behavior, the muscle is ultimately a scaled-up version of sarcomere.

An isotonic contraction occurs when a muscle undergoes a change in length under an applied load. Isotonic contractions can be either concentric or eccentric. For concentric contractions, the muscle tension exceeds the resistance, and the muscle shortens. For eccentric contractions, the muscle tension developed is less than resisting force, and the muscle elongates.

An isometric contraction occurs when the muscle does not or cannot change length, but the load in the muscle increases. An example of this is holding a weighted object in a fixed position. The load causes stretching and the muscle counteracts this by contracting and an increase in tension is experienced. Although there is no movement, energy is still expended in maintaining the increased tensile force in the muscle. Most movements of the body use a combination of isotonic and isometric contractions.

For example, the facial muscles (craniofacial muscles) are a group of about 20 flat skeletal muscles lying underneath the skin of the face and scalp. Most of them originate from bones or fibrous structures of the skull. With the exception of buccinator muscle, facial muscles are not surrounded by a fascia. These muscles are categorized into several groups: Muscles of the mouth (buccolabial group), Muscles of the nose (nasal group), Muscles of the cranium and neck (epicranial group), Muscles of the external ear (auricular group), and Muscles of the eyelid (orbital group). The specific location and attachments of the facial muscles enable them to produce movements of the face, such as smiling, grinning and frowning. Facial muscles are called muscles of facial expression or Mimetic muscles. All of the facial muscles are innervated by the facial nerve (CN VII) and vascularized by the facial artery.

The majority of the mouth muscles are connected by a fibromuscular hub onto which their fibers insert. This structure is called the modiolus, it is located at the angles of the mouth and it is primarily formed by the buccinator, orbicularis oris, risorius, depressor anguli oris and zygomaticus major muscles. For example, muscles of the mouth include Orbicularis Oris muscle, Risorius muscle, Buccinator muscle, Levator labii superioris, Depressor labii inferioris, Levator labii superioris alaeque nasi, Mentalis, Levator anguli oris, Depressor anguli oris, Zygomaticus major, and Zygomaticus minor. For example, muscles of the nose include Nasalis muscle and Procerus muscle. For example, muscles of the eyelid include Orbicularis oculi muscle and Corrugator supercilia muscle. For example, muscles of the cranium and neck include Occipitofrontalis muscle and Platysma muscle. For example, muscles of the external ear include Auricular muscles.

For a good finite element simulation, a precise representation of the underlying geometry is necessary. One way to obtain accurate geometries for muscles is the use of MRI/CT scan. Another way is to use the dissection of muscle, which is not applicable for in vivo tests. Our geometry is based on the Zygote model of human anatomy. The Zygote model offers a very accurate anatomical model of all the muscles and bones in a human body. This includes anatomical models for male and females.

The Zygote model came in mesh format (.obj) which is not suitable for finite element Applications. For the finite element method to work, the geometry had to be converted to a solid format. We made use of the software Rhinoceros to convert the mesh into a solid. The choice of Rhinoceros was based on its capabilities to handle NURBS, which is necessary when handling very complex geometries as facial muscles. After converting the mesh to a solid, we made use of the software GMSH to generate the finite element mesh.

FEM mesh: One of the most important aspects in the fem simulation, is to generate a smooth mesh. Since the geometry came from an external CAD software, the use of 3d-party software is necessary. GMSH is lightweight mesh generation software that can be used to produce Tetrahedra as well as Hexahedra meshes. In order to handle very complex geometries and to produce smooth well suited meshes for FEM simulations, the use of tetrahedra meshes was indispensable.

Fibers orientation: In contrast to other biological tissues, muscles display the ability of active contraction, and when activated, they contract along their fiber directions. In FEM simulations, it is hard to define the fiber orientation arrangement due to the complex geometries. Since we are using a B-spline-Solid for the geometrical representation of the muscles, we made use of isocurves extraction using Rhinoceros. The fibers orientation will be then determined as the tangent to the isocurve at a quadrature point.

In order to use isocurves for the fibers orientation description, a parametrization of this curves had to be performed. A parametrization was possible using the Cox-de Boor recursion relation

$${N}_{i , p} ( u ) = \frac{u - {u}_{i}}{{u}_{i + p - 1} - {u}_{i}} {N}_{i , p - 1} ( u ) + \frac{{u}_{i + p} - u}{{u}_{i + p} - {u}_{i + 1}} {N}_{i + 1 , p - 1} ( u ) ,$$

$$with$$

$${N}_{i , 0} ( u ) = \{ \begin{matrix}1 , & {u}_{i} \leq u < {u}_{i + 1} \\ 0 , & otherwise\end{matrix} ,$$

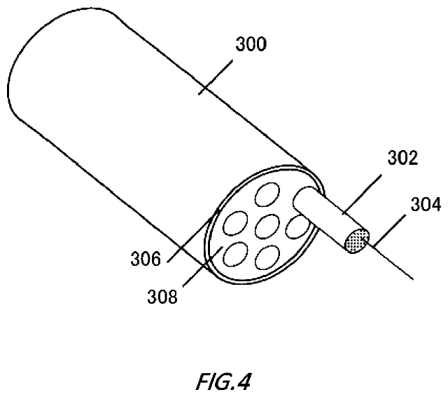

FIG. 5 schematically shows an example of isocurves extraction for fibers orientation.

Regarding linearized muscle model for skeletal muscle, a powerful tool to find good approximate numerical solutions for equations describing the muscles contraction is the finite element method. This method transforms the partial differential equations into a finite set of algebraic equations. This is accomplished by using an equivalent integral expression of the partial differential equations (e.g. via the use of weighted residuals formulation) and appropriate spatial and temporal discretization.

Numerical models for muscles date to 1938 by the experimental works of Hill. The classical Hill's muscle model consists of three components, namely, the contractile (CE), series (SE) and parallel (PE) elements. FIG. 6 schematically shows an example of HILL's functional model of the muscle.

Muscle consists of more than 70% water and behaves as nearly incompressible. The total stress in the muscle is the sum of the ground substance and the muscle fiber stress in each muscle group present, that is,

$$σ = {σ}_{m} + {σ}_{f} \qquad ( 1 )$$

σ_{f} is the stress in the fibers and σₘ is the stress in the matrix surrounding the fibers. Here σₘ is given by

$${σ}_{m} = {ℂ}_{m} ε \qquad ( 2 )$$

Where [symbol] is the constitutive tensor of the ground material, which is typically isotropic, and ε is the strain in the material.

For this work we use a linearized muscle model that is based on the classical hill's muscle model (nonlinear). The one-dimensional longitudinal muscle tension (in the direction of fibers) is the sum of the stresses in the SE and PE, that is,

$$T = {T}_{p} + {T}_{S} \qquad ( 3 )$$

The tension in the CE is equal to the tension in the SE,

$${T}_{C} = {T}_{S} \qquad ( 4 )$$

Generally, the stretch is related to the strain

$$λ = 1 + ε \qquad ( 5 )$$

For small strains, λ≈1 and the stress in the fiber, σ_{f} is given by

$${σ}_{j} = {λ}_{f} Tm ⊗ m ≃ Tm ⊗ m \qquad ( 6 )$$

Where T is the total tensile force in the fiber of each muscle group present.

The strain in a muscle fiber, ε_{f}, is given by

$${ε}_{f} = m \cdot ε m \qquad ( 7 )$$

The fiber stretch, λ_{f}, is assumed to split multiplicatively into CE and SE stretches λ_{c} and, λₛ so that

$${λ}_{f} = {λ}_{s} {λ}_{c} \qquad ( 8 )$$

Given an initial fiber length L₀, a deformed fiber length due to muscle contraction L^{c} and final length due to elastic deformation of fibers L, the stretches are defined as

$${λ}_{f} = \frac{L}{{L}_{0}} , {λ}_{c} = \frac{{L}^{c}}{{L}_{0}} , {λ}_{x} = \frac{L}{{L}^{c}} . \qquad ( 9 )$$

The multiplicative split of stretches has an advantage over the additive split method, commonly used in biomechanics, in that it does not require information on the partition of the initial fiber length between the CE and SE.

Using equation (5), we can now rewrite the multiplicative split equation (8) as

$${λ}_{f} = 1 + {ε}_{s} + {ε}_{c} {+}_{HIGHER - ORDER TERMS} . \qquad ( 10 )$$

Where, for small strains, the higher-order terms are assumed to be insignificant. Rearranging the terms in (10), and considering (5), we obtain a formulation for SE and CE strains in terms of fiber strain:

$${λ}_{f} - 1 ≃ ε \text{?} + {ε}_{c} \qquad ( 11 )$$

$$\text{?} \text{indicates text missing or illegible when filed}$$

### Hence

$${ε}_{f} ≃ {ε}_{s} + {ε}_{c} \qquad ( 12 )$$

The stress in the PE is given by

$${T}_{p} ( {ε}_{f} ) = {T}_{0} {f}_{p} ( {ε}_{f} ) \qquad ( 13 )$$

Linearization of fₚ gives

$$f \text{?} ( {ε}_{f} ) = {m}_{p} {ε}_{{f}_{WHEN}} {ε}_{f} > {0}_{AND} {0}_{OTHERWISE} . \qquad ( 14 )$$

$$\text{?} \text{indicates text missing or illegible when filed}$$

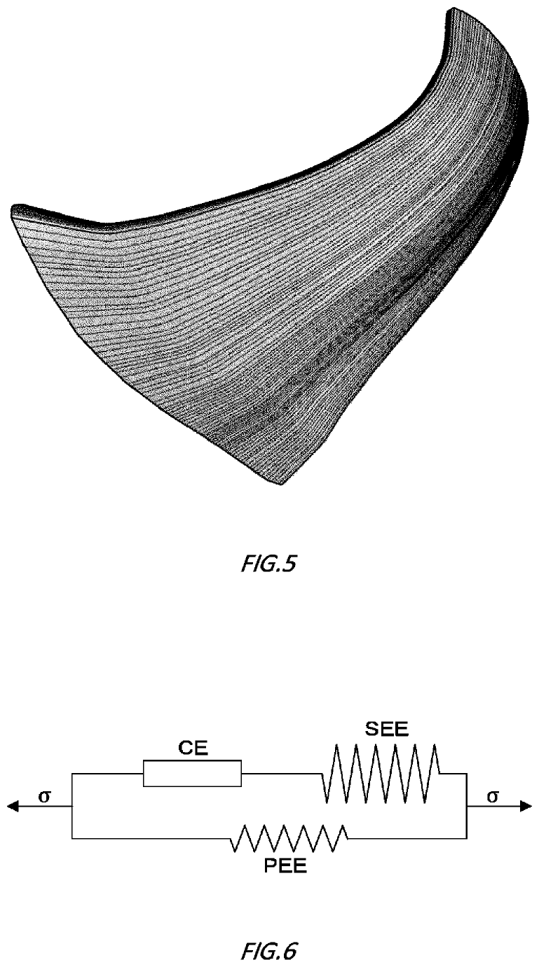

The resulting linearized stress-strain relation for the PE can be seen in the FIG. 7. Here, mₚ=2aA is the slope of the curve for ε_{f}>0, and T₀, a and A are material parameters.

The stress in the SE is given by

$$T \text{?} ( {ε}_{f} , {ε}_{c} ) = {T}_{0} {f}_{s} ( {ε}_{f} , {ε}_{c} ) \qquad ( 15 )$$

$$\text{?} \text{indicates text missing or illegible when filed}$$

Using Taylor expansion, and noting that for small displacement x, we have e^{x}≃1+x. Applying this approximation and the approximation in (12), it can be shown that

$$f \text{?} ( {ε}_{f} , {ε}_{c} ) = m \text{?} {( {ε}_{j} - {ε}_{c} )}_{WHEN} ε \text{?} \geq {0}_{AND} {0}_{OTHERWISE} . \qquad ( 16 )$$

$$\text{?} \text{indicates text missing or illegible when filed}$$

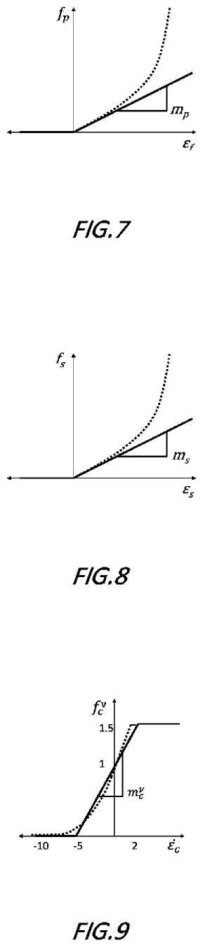

The resulting linearized stress-strain relation for the SE can be seen in FIG. 8. Here, mₛ=10 is the gradient of the straight line.

FIGS. 7 and 8 show linearised stress-strain relation for the parallel element (FIG. 7) and the series element (FIG. 8).

The stress in the CE is given by

$${T}_{c} ( {ε}_{c} , {\dot{ε}}_{c} , α ) = {T}_{0} {f}_{s}^{l} ( {ε}_{c} ) {f}_{c}^{v} ( {\dot{ε}}_{c} ) α ( t ) \qquad ( 17 )$$

Where α(t) is the activation function in (20).

Using (5) and (12) gives the relationships for f_{c}^{l}(ε_{c}) and f_{c}^{v}(ε_{c}) as

$${f}_{c}^{l} ( {ε}_{c} ) = {1}_{WHEN} - 0.5 \leq {ε}_{c} \leq {0.5}_{AND} {0}_{OTHERWISE} . \qquad ( 18 )$$

$$And$$

$$f \text{?} ( {\dot{ε}}_{c} ) = {0}_{WHEN} {\dot{ε}}_{c} < - {5}_{AND} \frac{1}{5} {\dot{ε}}_{c} + {1}_{WHEN} - 5 \leq {\dot{ε}}_{c} \leq {3}_{AND} {1.6}_{WHEN} {\dot{ε}}_{c} \leq {3}_{} \qquad ( 19 )$$

$$\text{?} \text{indicates text missing or illegible when filed}$$

The resulting linearized stress versus strain and stress versus strain-rate relations for the CE can be seen in FIGS. 9 and 10. FIG. 9 shows force-velocity relation of fully activated muscle tissue when CE is at optimal length. FIG. 10 shows force-length relation of muscle tissue due to an active force. The solid line in each of the FIGS. 9 and 10 illustrates the linearized function used for the linearized muscle model, superimposed on the original nonlinear functions, shown in broken line.

Muscle activation function. The time-dependent muscle activation function illustrated in FIG. 9 is given by the solution to the first-order differential equation:

$$α ( t , u ) = \frac{1}{{τ}_{r}} ( 1 - α ( t ) ) u ( t ) + \frac{1}{{τ}_{r}} {α}_{min} - α ( t ) ) ( 1 - u ( t ) ) . \qquad ( 20 )$$

Where τ^{r} and τ_{f} are rise and fall time constants for activation and deactivation of the muscle, respectively, αₘᵢₙ is the minimum value of the activation and u(t) is the neural excitation as a function of time given by

$$u ( t ) = {1}_{WHEN} 0 < t \leq {1}_{AND} {0}_{OTHERWISE} . \qquad ( 21 )$$

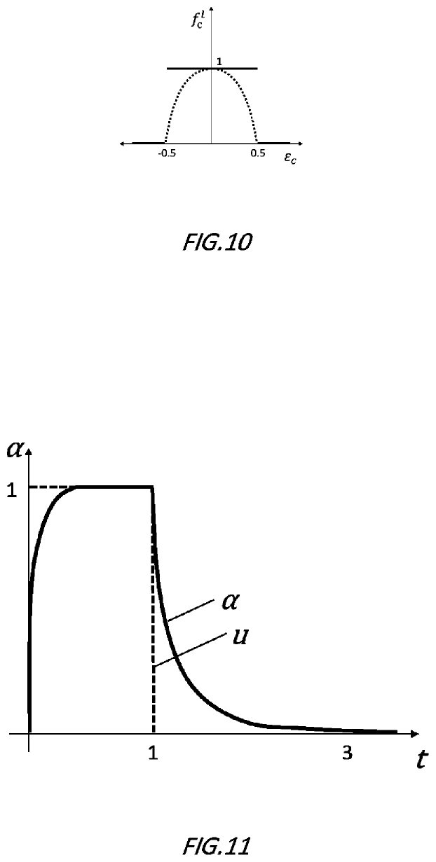

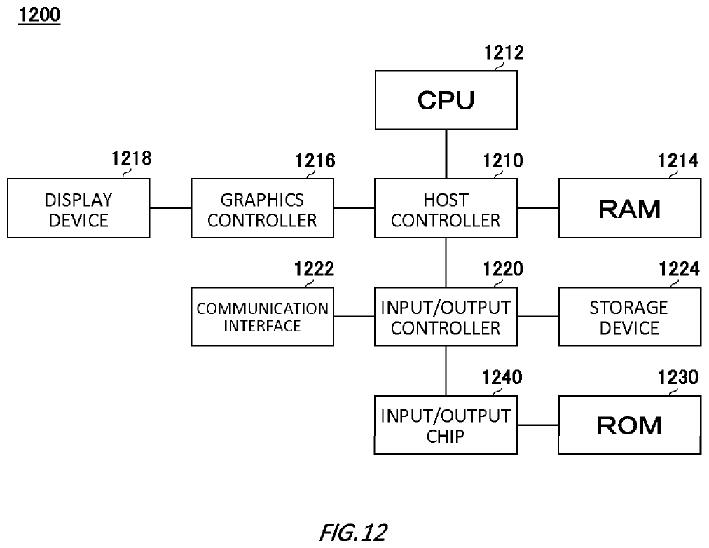

FIG. 11 shows example of an activation function α(t) for a given neural excitation u(t) versus time (s).

The backward Euler method is an implicit method that uses the current and previous states of the system to find the solution at the current state. Using this method, the activation rate in (20) can be approximated by

$$\dot{α} = \frac{α \text{?} - {α}^{n - 1}}{Δ t} \qquad ( 22 )$$

$$\text{?} \text{indicates text missing or illegible when filed}$$

Where Δt is the time-step size, αⁿ is the activation at the current time step and αⁿ⁻¹ is the activation at the previous time step. Applying the backward Euler method to the activation function in (20), using the neural input function in (21) and solving for αⁿ gives the solution as

$$α \text{?} ( \text{?} ) = {\frac{{α}^{n - 1} τ \text{?} τ \text{?} Δ t τ \text{?}}{τ \text{?} τ \text{?} + Δ t τ \text{?}}}_{{WHEN}^{u = 1} AND} α \text{?} ( \text{?} ) = {\frac{{α}^{n - 1} τ \text{?} τ \text{?} Δ t α \text{?} τ \text{?}}{τ \text{?} τ \text{?} + Δ t τ \text{?}}}_{{WHEN}^{u = 0}} \qquad ( 23 )$$

$$\text{?} \text{indicates text missing or illegible when filed}$$

This implicit method allows one to determine the activation level at the current increment in time on the basis of the activation level at the previous time increment. It is in this way that the activation function is handled computationally.

Linearized muscle model parameters. The parameters of the constitutive equation were obtained from multiaxial testing data, for the work (Humphrey J D, Yin FCP. On constitutive relations and finite deformations of passive cardiac tissue: I. a pseudo-strain-energy function. Journal of Biomechanical Engineering 1987; 109:298-304.), and are given as

$$c = {3.87}_{gf / {cm}^{2}} , b = 23.46 , A = 8.568 \times {10}_{gf / {cm}^{2}}^{- 4} , a = 12.43 .$$

In addition, the activation stress constant is chosen as

$${T}_{0} = {6280}_{gf / {cm}^{2}} . \qquad ( 24 )$$

It can be shown that the shear modulus is related to the young's modulus as follows

$$G = \frac{E}{2 ( 1 + v )} . \qquad ( 25 )$$

Using the parameters b and c, a relationship between young's modulus and the Poisson's ratio is given as

$$E = 2 ( 1 + v ) bc \qquad ( 26 )$$

Thus, for a selected Poisson's ratio v=0.45, young modulus is given as E≈26000_{Pa.}.

Finite element approximations. The weak form of the equilibrium equation of the linearized muscle model boundary value is given as

$${\int }_{Ω} σ ( u , {ε}_{c} ) : ε ( v ) d Ω = {\int }_{Ω} f \cdot vd Ω . \qquad ( 27 )$$

Expanding equation (3) using the relationships in (4) and (6) gives

$$σ = {ℂ}_{m} ε + {T}_{0} {\sum }_{i} [ {βε}_{f}^{( i )} + {γε}_{c}^{n ( i )} ] {m}^{( i )} ⊗ {m}^{( i )} , \qquad ( 28 )$$

Where n is the current solution increment, and the introduced parameters are defined as

$$β = {m}_{p} + {m}_{s} \qquad ( 29 )$$

$$γ = - {m}_{s} \qquad ( 30 )$$

The CE stress must be equal to the SE stress, that is,

$${σ}_{c} = {σ}_{s} \qquad ( 31 )$$

Expanding the CE and SE element stress functions for each fiber gives

$${f}_{c}^{l} ( {m}_{c}^{v} {ε}_{c} + {c}_{c}^{v} ) {α}^{n} = {m}_{s} ( {ε}_{f} - {ε}_{c}^{n} ) . \qquad ( 32 )$$

Using the backward Euler method, the CE strain rate \dot{ε}_{c} can be approximated by

$${\dot{ε}}_{c} = \frac{{ε}_{c}^{n} - {ε}_{c}^{n - 1}}{Δ t} . \qquad ( 33 )$$

Where ε_{c}ⁿ and ε_{c}ⁿ⁻¹ are the current and prior CE strains.

Combining (32) and (33), the current CE strain in a fiber is then given by

$${ε}_{c}^{n} = {ηϕε}_{j} + ϕ ( {ε}_{c}^{n - 1} + κ Δ t ) , \qquad ( 34 )$$

Where, assuming f_{c}^{l}≠0, αⁿ≠0, m_{c}^{v}≠0, parameters are formed by rearrangement of terms as

$$η = \frac{m , Δ t}{{m}_{c}^{v} {f}_{c}^{l} {a}^{n}} , ϕ = {( 1 + η )}^{- 1} , k = - \frac{{c}_{c}^{v}}{{m}_{c}^{v}} \qquad ( 35 )$$

Substitution of using (34) into (28) gives

$$σ = {ℂ}_{m} ε + {T}_{0} {\sum }_{i} [ ( β + γηϕ ) {ε}_{f}^{( i )} + γϕ ( {ε}_{τ}^{( n - 1 ) ( i )} + κΔ t ] {m}^{( i )} ⊗ {m}^{( i )} . \qquad ( 36 )$$

Equation (36) together with the weak equilibrium equation in (27) is to be solved using the FEM.

Applying (27) to (36) to the linear system of equations,

$${Kd}^{n} = F , \qquad ( 37 )$$

where, K, dⁿ and F and are the stiffness matrix, displacement vector and force vector, respectively.

FIG. 12 schematically shows an example of a hardware configuration of a computer 1200 functioning as the information processing apparatus 100. A program installed in the computer 1200 can cause the computer 1200 to function as one or more “units” of an apparatus according to the present embodiment, or cause the computer 1200 to perform operations associated with the apparatus or perform one or more “units” thereof according to the present embodiment, and/or cause the computer 1200 to perform the process according to the present embodiment or perform the steps of the process. Such a program may be executed by a CPU 1212 to cause the computer 1200 to perform particular operations associated with some or all of the blocks in the flowcharts and block diagrams described in the present specification.

The computer 1200 according to the present embodiment includes the CPU 1212, a RAM 1214, and a graphics controller 1216, which are interconnected by a host controller 1210. The computer 1200 also includes input/output units such as a communication interface 1222, a storage device 1224, a DVD drive, and an IC card drive, which are connected to the host controller 1210 via an input/output controller 1220. The DVD drive may be a DVD-ROM drive, a DVD-RAM drive, and the like. The storage device 1224 may be a hard disk drive, a solid-state drive, and the like. The computer 1200 also includes a ROM 1230 and a legacy input/output unit such as a keyboard, which are connected to the input/output controller 1220 via an input/output chip 1240.

The CPU 1212 operates according to the programs stored in the ROM 1230 and the RAM 1214, thereby controlling each unit. The graphics controller 1216 obtains image data which is generated by the CPU 1212 in a frame buffer or the like provided in the RAM 1214 or in itself so as to cause the image data to be displayed on a display device 1218.

The communication interface 1222 communicates with other electronic devices via a network. The storage device 1224 stores a program and data used by the CPU 1212 in the computer 1200. The DVD drive reads the programs or the data from the DVD-ROM or the like, and provides the storage device 1224 with the programs or the data. The IC card drive reads programs and data from an IC card and/or writes programs and data into the IC card.

The ROM 1230 stores, in itself, a boot program or the like that is executed by the computer 1200 during activation, and/or a program that depends on hardware of the computer 1200. The input/output chip 1240 may also connect various input/output units via a USB port, a parallel port, a serial port, a keyboard port, a mouse port, or the like to the input/output controller 1220.

A program is provided by the computer-readable storage medium such as the DVD-ROM or the IC card. The program is read from the computer-readable storage medium, installed into the storage device 1224, RAM 1214, or ROM 1230, which are also examples of a computer-readable storage medium, and executed by the CPU 1212. Information processing written in these programs is read by the computer 1200, and provides cooperation between the programs and the various types of hardware resources described above. A device or method may be constituted by realizing the operation or processing of information in accordance with the usage of the computer 1200.

For example, when a communication is executed between the computer 1200 and an external device, the CPU 1212 may execute a communication program loaded in the RAM 1214, and instruct the communication interface 1222 to process the communication based on the processing written in the communication program. The communication interface 1222, under a control of the CPU 1212, reads transmission data stored on a transmission buffer region provided in a recording medium such as the RAM 1214, the storage device 1224, the DVD-ROM, or the IC card, and transmits the read transmission data to a network or writes reception data received from a network to a reception buffer region or the like provided on the recording medium.

In addition, the CPU 1212 may cause all or a necessary portion of a file or a database to be read into the RAM 1214, the file or the database having been stored in an external recording medium such as the storage device 1224, the DVD drive (the DVD-ROM), the IC card, etc., and execute various types of processing on the data on the RAM 1214. Then, the CPU 1212 may write the processed data back in the external recording medium.

Various types of information, such as various types of programs, data, tables, and databases, may be stored in the recording medium to undergo information processing. The CPU 1212 may execute, on the data read from the RAM 1214, various types of processing including various types of operations, information processing, conditional judgement, conditional branching, unconditional branching, information retrieval/replacement, or the like described throughout the present disclosure and specified by instruction sequences of the programs, to write the results back to the RAM 1214. In addition, the CPU 1212 may retrieve information in a file, a database, or the like in the recording medium. For example, when a plurality of entries, each having an attribute value of a first attribute associated with an attribute value of a second attribute, are stored in the recording medium, the CPU 1212 may search for an entry whose attribute value of the first attribute matches a designated condition, from among the plurality of entries, and read the attribute value of the second attribute stored in the entry, thereby obtaining the attribute value of the second attribute associated with the first attribute satisfying a predetermined condition.

The program or software module described above may be stored in a computer-readable storage medium on the computer 1200 or near the computer 1200. In addition, a recording medium such as a hard disk or a RAM provided in a server system connected to a dedicated communication network or the Internet can be used as the computer-readable storage medium, thereby providing the program to the computer 1200 via the network.

Blocks in the flowcharts and block diagrams according to the present embodiment may represent steps of processes in which operations are performed or “units” of apparatuses responsible for performing operations. A particular step and “unit” may be implemented by dedicated circuitry, programmable circuitry supplied along with a computer-readable instruction stored on a computer-readable storage medium, and/or a processor supplied along with the computer-readable instruction stored on the computer-readable storage medium. The dedicated circuitry may include a digital and/or analog hardware circuit, or may include an integrated circuit (IC) and/or a discrete circuit. The programmable circuitry may include, for example, a reconfigurable hardware circuit including logical AND, logical OR, logical XOR, logical NAND, logical NOR, and other logical operations, and a flip-flop, a register, and a memory element, such as a field-programmable gate array (FPGA) and a programmable logic array (PLA).

A computer-readable storage medium may include any tangible device that can store instructions to be executed by a suitable device, and as a result, the computer-readable storage medium having instructions stored in the tangible device comprises an article of manufacture including instructions which can be executed to create means for executing operations specified in the flowcharts or block diagrams. Examples of the computer-readable storage medium may include an electronic storage medium, a magnetic storage medium, an optical storage medium, an electromagnetic storage medium, a semiconductor storage medium, and the like. More specific examples of the computer-readable storage medium may include a floppy (registered trademark) disk, a diskette, a hard disk, a random access memory (RAM), a read only memory (ROM), an erasable programmable read only memory (EPROM or flash memory), an electrically erasable programmable read only memory (EEPROM), a static random access memory (SRAM), a compact disk read only memory (CD-ROM), a digital versatile disc (DVD), a Blu-ray (registered trademark) disc, a memory stick, an integrated circuit card, or the like.

Computer-readable instructions may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk (registered trademark), JAVA (registered trademark), C++, etc., and conventional procedural programming languages, such as the “C” programming language or similar programming languages.

Computer-readable instructions may be provided to a processor of a general purpose computer, special purpose computer, or other programmable data processing apparatus, or to programmable circuitry, locally, or via a local area network (LAN) or a wide area network (WAN) such as the Internet, etc., such that it is possible for a processor of a general purpose computer, special purpose computer, or other programmable data processing apparatus, or for programmable circuitry to execute the computer-readable instructions to create means for performing operations specified in the flowcharts or block diagrams. Examples of the processor include a computer processor, a processing unit, a microprocessor, a digital signal processor, a controller, a microcontroller, and the like.

While the embodiments of the present invention have been described, the technical scope of the invention is not limited to the above described embodiments. It is apparent to persons skilled in the art that various alterations or improvements can be added to the above described embodiments. It is also apparent from the scope of the claims that the embodiments added with such alterations or improvements can be included in the technical scope of the invention. The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

While the embodiments of the present invention have been described, the technical scope of the invention is not limited to the above described embodiments. It is apparent to persons skilled in the art that various alterations or improvements can be added to the above described embodiments. It is also apparent from the scope of the claims that the embodiments added with such alterations or improvements can be included in the technical scope of the invention. The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

20: network; 100: information processing apparatus; 102: storage unit; 104: model generation unit; 106: simulation unit; 110: transmission unit; 112: display control unit; 114: process execution unit; 200: communication terminal; 300: muscle fiber; 302: myofibrils; 304: muscle filaments; 306: sarcolemma; 308: sarcoplasm; 1200: computer; 1210: host controller; 1212: CPU; 1214: RAM; 1216: graphics controller; 1218: display device; 1220: input/output controller; 1222: communication interface; 1224: storage device; 1230: ROM; 1240: input/output chip.

What is claimed is:

1. An information processing apparatus comprising:
a model generation unit that generates, by simulating contraction of a plurality of muscle fibers which make up a muscle, a muscle model that simulates a movement of the muscle; and
a simulation unit that simulates, by using the muscle model to simulate movements of a plurality of muscles which are included in a human face, a movement of the human face.

2. The information processing apparatus according to claim 1, wherein
the model generation unit uses a finite element method to generate the muscle model.

3. The information processing apparatus according to claim 1, wherein
the model generation unit divides, into a plurality of groups, the plurality of muscle fibers which make up the muscle, and generates, for one or some of the plurality of groups, the muscle model that simulates contraction of each of a plurality of muscle fibers which are included in the one or some of the plurality of groups.

4. The information processing apparatus according to claim 3, wherein
the model generation unit divides, into a plurality of groups, the plurality of muscle fibers which make up the muscle in descending order of influence on the movement of the muscle, and generates, for a group which has a greatest influence on the movement of the muscle among the plurality of groups, the muscle model that simulates contraction of each of a plurality of muscle fibers which are included in the group.

5. The information processing apparatus according to claim 3, wherein
the model generation unit generates, for one or some of the plurality of groups, the muscle model that simulates contraction of only one or some of a plurality of muscle fibers which are included in the one or some of the plurality of groups.

6. The information processing apparatus according to claim 3, wherein
the model generation unit generates, for one or some of the plurality of groups, the muscle model that integrally simulates contraction of a plurality of muscle fibers which are included in the one or some of the plurality of groups.

7. The information processing apparatus according to claim 1, wherein
the model generation unit generates the muscle model that simulates contraction of each of a plurality of muscle fibers which are located at an external boundary of the muscle and simulates contraction of only one or some of a plurality of muscle fibers which are located at a location other than the boundary, among the plurality of muscle fibers which make up the muscle.

8. The information processing apparatus according to claim 1, wherein
the model generation unit generates the muscle model that simulates contraction of each of a plurality of muscle fibers which have higher degree of freedom and simulates contraction of only one or some of a plurality of muscle fibers which have lower degrees of freedom, among the plurality of muscle fibers which make up the muscle.

9. A non-transitory computer-readable storage medium having stored thereon a program for causing a computer to function as:
a model generation unit that generates, by simulating contraction of a plurality of muscle fibers which make up a muscle, a muscle model that simulates a movement of the muscle; and
a simulation unit that simulates, by using the muscle model to simulate movements of a plurality of muscles which are included in a human face, a movement of the human face.

10. An information processing method that is executed by a computer, the information processing method comprising:
generating, by simulating contraction of a plurality of muscle fibers which make up a muscle, a muscle model that simulates a movement of the muscle; and
simulating, by using the muscle model to simulate movements of a plurality of muscles which are included in a human face, a movement of the human face.
